(19) United States
(12) Patent Application Publication
(10) Pub. No.: US 2026/0104681 A1
(43) Pub. Date: Apr. 16, 2026

(54) Reinforcement Learning System for Optimizing Selective Extraction of Lithium from Brines

(71) Applicant: Mariana Minerals Co., San Francisco, CA (US)

(72) Inventors: Turner Boris CALDWELL, San Francisco, CA (US); Juan Carlos LOZANO VAN DE VEN, San Francisco, CA (US); Brett Allen RABE, San Francisco, CA (US)

(21) Appl. No.: 19/360,591

(22) Filed: Oct. 16, 2025

Related U.S. Application Data
(60) Provisional application No. 63/708,056, filed on Oct. 16, 2024.

(51) Int. Cl. G05B 13/04; G06F 30/27

(52) U.S. Cl. CPC G05B 13/042; G06F 30/27

(57) ABSTRACT

According to one or more embodiments, a method, computer system, and computer program product for optimizing extraction of lithium through reinforcement learning are provided. The method may include receiving measurement data from one or more sensors corresponding to a current set of operational parameters associated with a direct lithium extraction process in one or more columns. A physical simulation of the direct lithium extraction process is generated based on the received measurement data and the current set of operational parameters. A set of optimal operational parameters for the one or more columns is identified based on the generated physical simulation. The identified set of optimal operational parameters is configured to maximize extraction of lithium through the direct lithium extraction process. The current set of operational parameters is adjusted based on the identified set of optimal operational parameters.

### FIELD

This disclosure relates generally to field of machine learning, and more particularly to reinforcement learning.

### BACKGROUND

Direct Lithium Extraction (DLE) is a technology that extracts lithium from aqueous solutions using specialized materials. This method bypasses the need for evaporation ponds allowing for faster extraction rates, higher overall lithium recovery, and minimized environmental impact. DLE technologies utilize specialized adsorbent materials, membranes, or solvent extraction processes to capture lithium ions selectively. By targeting lithium specifically, DLE methods minimize impurities and enable the production of high-purity lithium compounds, which can be used directly in battery manufacturing.

### SUMMARY

Embodiments relate to a method, system, and computer program product for optimizing extraction of lithium through reinforcement learning. The principles disclosed herein underlying the extraction of lithium apply to other material extraction plants and facilities, as well as other like industrial and manufacturing settings.

According to one aspect, a method for optimizing extraction of lithium through reinforcement learning is provided. The method may include receiving measurement data from one or more sensors corresponding to a current set of operational parameters associated with a direct lithium extraction process in one or more columns. A physical simulation of the direct lithium extraction process is generated based on the received measurement data and the current set of operational parameters. A set of optimal operational parameters for the one or more columns is identified based on the generated physical simulation. The identified set of optimal operational parameters is configured to maximize extraction of lithium through the direct lithium extraction process. The current set of operational parameters is adjusted based on the identified set of optimal operational parameters.

According to another aspect, a computer system for optimizing extraction of lithium through reinforcement learning is provided. The computer system may include one or more processors, one or more computer-readable memories, one or more computer-readable tangible storage devices, and program instructions stored on at least one of the one or more storage devices for execution by at least one of the one or more processors via at least one of the one or more memories, whereby the computer system is capable of performing a method. The method may include receiving measurement data from one or more sensors corresponding to a current set of operational parameters associated with a direct lithium extraction process in one or more columns. A physical simulation of the direct lithium extraction process is generated based on the received measurement data and the current set of operational parameters. A set of optimal operational parameters for the one or more columns is identified based on the generated physical simulation. The identified set of optimal operational parameters is configured to maximize extraction of lithium through the direct lithium extraction process. The current set of operational parameters is adjusted based on the identified set of optimal operational parameters.

According to yet another aspect, a computer program product for optimizing extraction of lithium through reinforcement learning is provided. The computer program product may include one or more computer-readable storage devices and program instructions stored on at least one of the one or more computer-readable storage devices. The program instructions are executable by a processor for performing a method that may accordingly include receiving measurement data from one or more sensors corresponding to a current set of operational parameters associated with a direct lithium extraction process in one or more columns. A physical simulation of the direct lithium extraction process is generated based on the received measurement data and the current set of operational parameters. A set of optimal operational parameters for the one or more columns is identified based on the generated physical simulation. The identified set of optimal operational parameters is configured to maximize extraction of lithium through the direct lithium extraction process. The current set of operational parameters is adjusted based on the identified set of optimal operational parameters.

### BRIEF DESCRIPTION OF THE DRAWINGS

These and other objects, features and advantages will become apparent from the following detailed description of illustrative embodiments, which is to be read in connection with the accompanying drawings. The various features of the drawings are not to scale as the illustrations are for clarity in facilitating the understanding of one skilled in the art in conjunction with the detailed description. In the drawings:

FIG. 1 illustrates a networked computer environment according to at least one embodiment;

FIG. 2A is a block diagram of a system for optimizing extraction of lithium through reinforcement learning, according to at least one embodiment;

FIG. 2B is a block diagram of an example lithium extraction system depicting a detailed view of one or more extraction columns and a piping and valve system as depicted in FIG. 2A, according to at least one embodiment;

FIG. 2C is a block diagram of a reinforcement learning module and a physical simulator as depicted in FIG. 2A, according to at least one embodiment;

FIG. 3 is an operational flowchart illustrating the steps carried out by a program that optimizes extraction of lithium through reinforcement learning; and

FIG. 4 is a block diagram of internal and external components of computers and servers depicted in FIG. 1 according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. Those structures and methods may, however, be embodied in many different forms and should not be construed as limited to the exemplary embodiments set forth herein. Rather, these exemplary embodiments are provided so that this disclosure will be thorough and complete and will fully convey the scope to those skilled in the art. In the description, details of well-known features and techniques may be omitted to avoid unnecessarily obscuring the presented embodiments.

Embodiments relate generally to the field of machine learning, and more particularly to reinforcement learning. The following described exemplary embodiments provide a system, method and computer program to, among other things, optimize the selective extraction of lithium from brines through a reinforcement learning algorithm. Therefore, some embodiments have the capacity to improve the field of computing by using reinforcement learning and a physically linked simulator to autonomously optimize the control of lithium extraction in real-time, independent of the specific direct lithium extraction (DLE) technology used. For example, the system, method, and computer program described herein may allow a computer to maximize lithium recovery in DLE techniques while minimizing operational costs through the application of reinforcement learning in process control.

As previously described, direct lithium extraction (DLE) is a technology that extracts lithium from aqueous solutions using specialized materials. This method bypasses the need for evaporation ponds allowing for faster extraction rates, higher overall lithium recovery, and minimized environmental impact. DLE technologies utilize specialized adsorbent materials, membranes, or solvent extraction processes to capture lithium ions selectively. By targeting lithium specifically, DLE methods minimize impurities and enable the production of high-purity lithium compounds, which can be used directly in battery manufacturing.

However, current direct lithium extraction (DLE) technologies rely on a combination of static configuration parameters and process control parameters that are updated infrequently and do not adapt to real-time variations in feed composition, leading to suboptimal recovery rates and increased operational costs. It may be advantageous, therefore, to use a reinforcement learning (RL)-based control system that optimizes the selective extraction of lithium from brines. Sensors may be installed at the inlet and outlet of selected points in the process. These sensors may provide real-time data on the concentration of lithium and other relevant impurities and process conditions. The sensor data may be used in conjunction with a physical simulator combined with a probabilistic linking algorithm to estimate a posterior probability of the simulator's physical parameters given the observed data. The estimation of the state of the physical system as derived by the linking algorithm and the physical simulator is used by an RL control algorithm as a world model. The RL algorithm may optimize the process behavior by adjusting parameters dynamically, based on the linked simulator, to enhance the selective recovery of lithium. Reinforcement learning may learn a policy that maps states of the world to actions a system should take.

The embodiments disclosed herein may have potential applications in large-scale lithium extraction operations, particularly in regions where brine compositions fluctuate significantly. It may be appreciated that while the embodiments disclosed herein are described with respect to lithium extraction, the disclosed embodiments may also be applied in other industries where selective extraction of valuable elements from brines is required.

Aspects are described herein with reference to flowchart illustrations and/or block diagrams of methods, apparatus (systems), and computer readable media according to the various embodiments. It will be understood that each block of the flowchart illustrations and/or block diagrams, and combinations of blocks in the flowchart illustrations and/or block diagrams, can be implemented by computer readable program instructions.

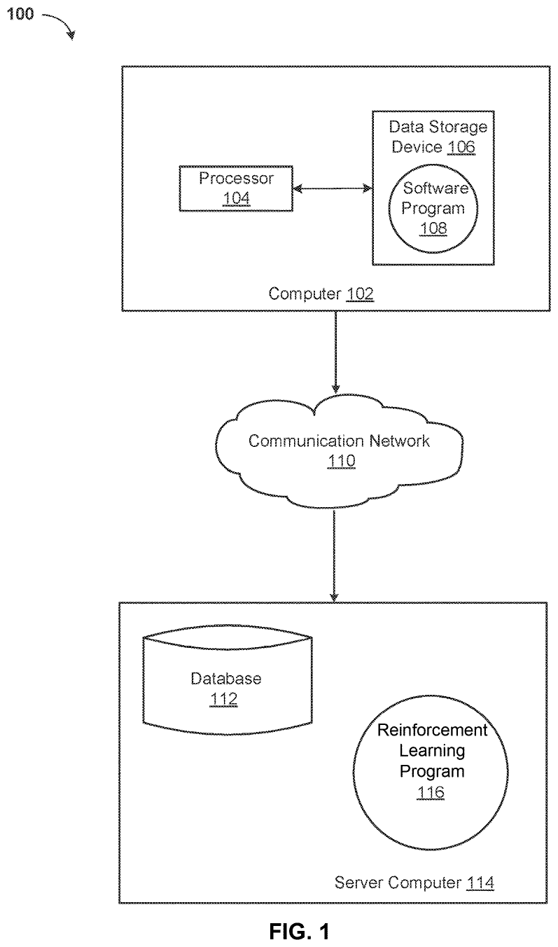

The following described exemplary embodiments provide a system, method and computer program that optimizes extraction of lithium through reinforcement learning. Referring now to FIG. 1, a functional block diagram of a networked computer environment illustrating a Direct Lithium Extraction system 100 (hereinafter “system”) for optimizing extraction of lithium through reinforcement learning. It should be appreciated that FIG. 1 provides only an illustration of one implementation and does not imply any limitations with regard to the environments in which different embodiments may be implemented. Many modifications to the depicted environments may be made based on design and implementation requirements.

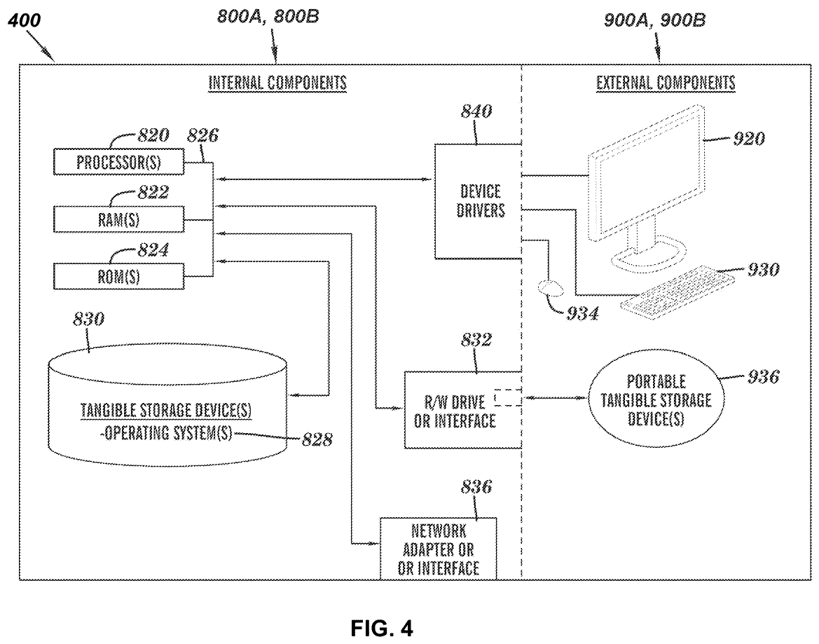

The system 100 may include a computer 102 and a server computer 114. The computer 102 may communicate with the server computer 114 via a communication network 110 (hereinafter “network”). The computer 102 may include a processor 104 and a software program 108 that is stored on a data storage device 106 and is enabled to interface with a user and communicate with the server computer 114. As will be discussed below with reference to FIG. 4 the computer 102 may include internal components 800A and external components 900A, respectively, and the server computer 114 may include internal components 800B and external components 900B, respectively. The computer 102 may be, for example, a mobile device, a telephone, a personal digital assistant, a netbook, a laptop computer, a tablet computer, a desktop computer, or any type of computing devices capable of running a program, accessing a network, and accessing a database.

The server computer 114, which may be used for optimizing extraction of lithium through reinforcement learning is enabled to run a Reinforcement Learning Program 116 (hereinafter “program”) that may interact with a database 112. The Reinforcement Learning Program method is explained in more detail below with respect to FIG. 4. In one embodiment, the computer 102 may operate as an input device including a user interface while the program 116 may run primarily on server computer 114. In an alternative embodiment, the program 116 may run primarily on one or more computers 102 while the server computer 114 may be used for processing and storage of data used by the program 116. It should be noted that the program 116 may be a standalone program or may be integrated into a larger reinforcement learning program.

It should be noted, however, that processing for the program 116 may, in some instances be shared amongst the computers 102 and the server computers 114 in any ratio, including solely on one of the computer 102 or the server computer 114. In another embodiment, the program 116 may operate on more than one computer, server computer, or some combination of computers and server computers, for example, a plurality of computers 102 communicating across the network 110 with a single server computer 114. In another embodiment, for example, the program 116 may operate on a plurality of server computers 114 communicating across the network 110 with a plurality of client computers. Alternatively, the program may operate on a network server communicating across the network with a server and a plurality of client computers.

The network 110 may include wired connections, wireless connections, fiber optic connections, or some combination thereof. In general, the network 110 can be any combination of connections and protocols that will support communications between the computer 102 and the server computer 114. The network 110 may include various types of networks, such as, for example, a local area network (LAN), a wide area network (WAN) such as the Internet, a telecommunication network such as the Public Switched Telephone Network (PSTN), a wireless network, a public switched network, a satellite network, a cellular network (e.g., a fifth generation (5G) network, a long-term evolution (LTE) network, a third generation (3G) network, a code division multiple access (CDMA) network, etc.), a public land mobile network (PLMN), a metropolitan area network (MAN), a private network, an ad hoc network, an intranet, a fiber optic-based network, or the like, and/or a combination of these or other types of networks. The number and arrangement of devices and networks shown in FIG. 1 are provided as an example. In practice, there may be additional devices and/or networks, fewer devices and/or networks, different devices and/or networks, or differently arranged devices and/or networks than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of system 100 may perform one or more functions described as being performed by another set of devices of system 100.

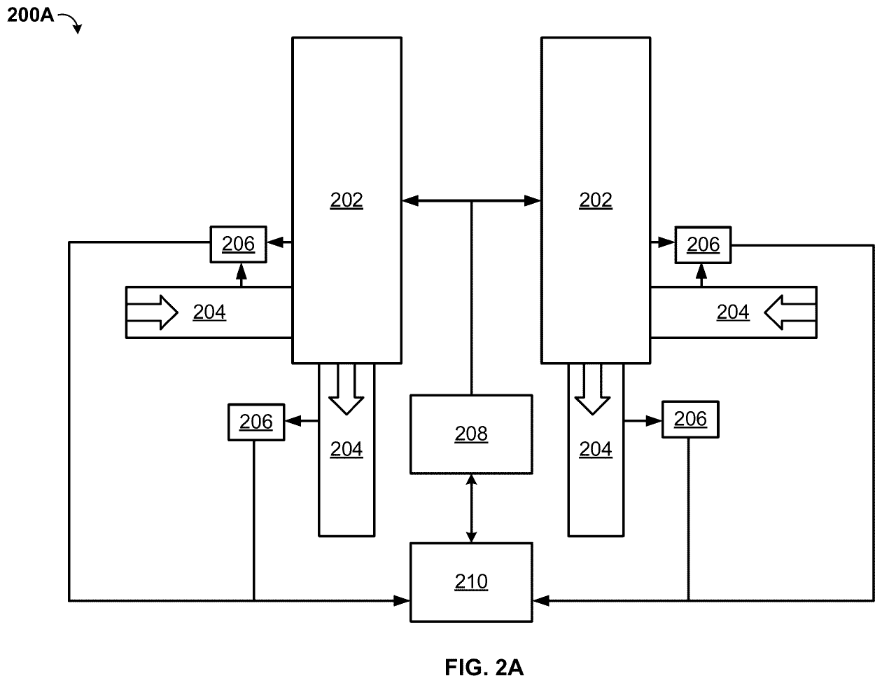

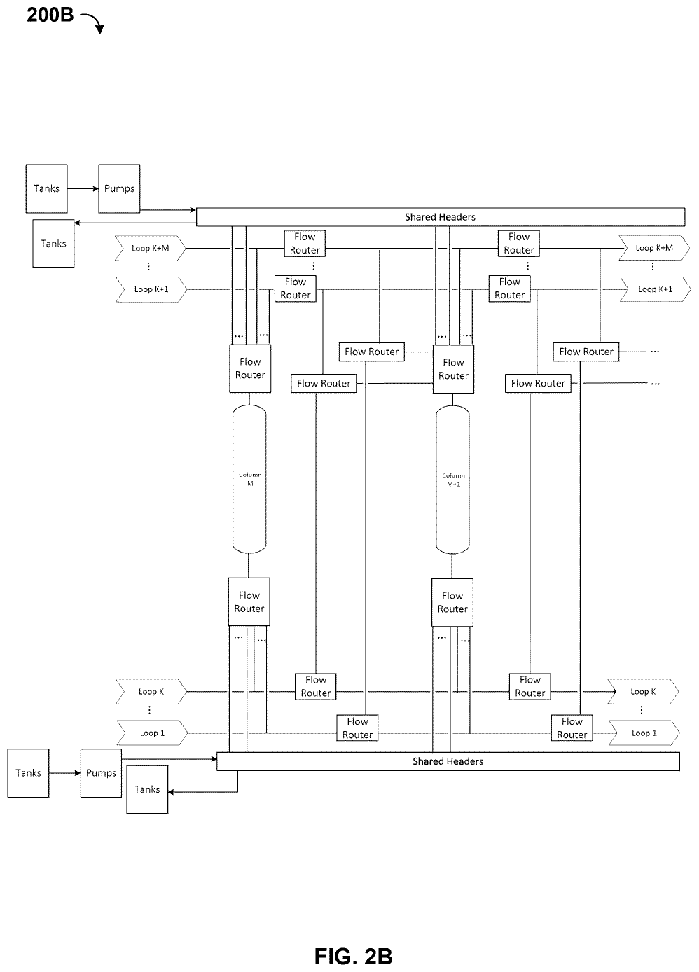

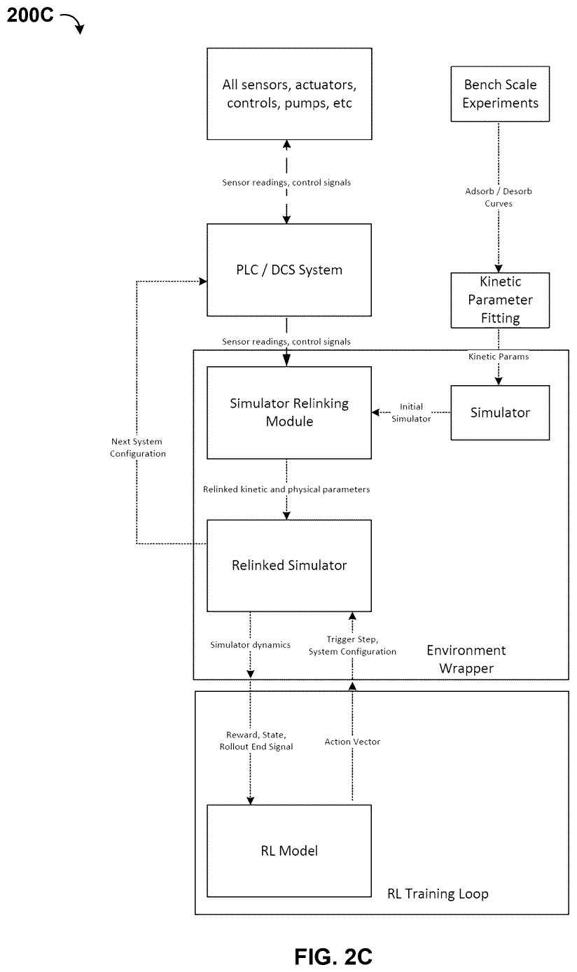

Referring now to FIG. 2A, a block diagram of a system 200A for optimization of lithium extraction through reinforcement learning is depicted, according to at least one embodiment. The system 200A may include, among other things, one or more extraction columns 202, a piping and valve system 204, one or more sensors 206, a reinforcement learning module 208, and a physical simulator 210.

The one or more extraction columns 202 may be configured for the extraction of lithium or other metal ions (e.g. Group 1, Group 2, etc.) from brine or other solutions. The columns may carry out an extraction process in several stages. These may include, among other things, a loading stage, in which lithium bearing brine passes through the extraction columns 202 and lithium is selectively captured and retained in media in the extraction columns 202; a brine displacement stage, in which the brine remaining in a loaded extraction column 202 is displaced using a displacement flush solution; a stripping stage, in which the lithium captured by the media in the extraction columns 202 is removed; and a column regeneration stage, in which the extraction columns 202 are regenerated for reuse.

The piping and valve system 204 may be operatively coupled to the extraction columns 202 to allow for inflow of brine and outflow of reaction products and by-products from the extraction columns 202. The piping and valve system may allow the reinforcement learning module 208 to update the configuration of the extraction columns 202 without human intervention or operational downtime. The piping and valve system 204 may allow the reinforcement learning module 208 to explore and exploit a wide range of configurations of the extraction columns 202 and may choose a best configuration based on the incoming brine feed composition and quantity.

The one or more sensors 206 may be selectively placed to record measurements from the one or more extraction columns 202. For example, the sensors 206 may be placed at the inlet and outlet of each stage of the process within the extraction columns 202 or the piping and valve system 204. The sensors 206 may include, among other things, flow meters and temperature, pH, and oxidation-reduction potential (ORP) sensors. Data from the sensors 206 may be provided to the physical simulator 210, which may link simulation parameters to the sensor data to “true up” the physical simulator with physical behavior of the system 200A. The physical simulator 210 may then pass the data from the one or more sensors 206 to the reinforcement learning module 208.

The sensor data, particularly the composition data, may be used to optimize the process because the efficiency and efficacy of the extraction process may be directly related to the composition of the inflowing brine as well as the composition of the feed flowing out from different stages in the process. The piping design for the system that feeds brine to the sensors 206 from various points in the process may specifically be designed to minimize scaling and other damage to the sensors 206 or the piping and valve system 204 that may require operational downtime to repair. Finally, the choice of sensor locations and the design of the sampling system may be specifically designed to maximize effectiveness and minimize the cost of additional sensors 206.

The physical simulator 210 may be a physically grounded simulator that is parameterized using data from vendors and experiments conducted at bench- and pilot-scale to approximate the behavior of the system 200A for long time periods. To run many iterations of the simulator in parallel, the physical simulator 210 may utilize, for example, graphics processing unit (GPU) architectures for efficiency in running the physical simulator 210. The physical simulator 210 may be used to, among other things, forecast the behavior of the system 200A based on control actions specified by a reinforcement learning (RL) control algorithm of the reinforcement learning module 208. The physical simulator 210 may be used to derive features that represent properties of the system that may otherwise be difficult to observe in order to guide the choices made by the RL control algorithm of the reinforcement learning module 208. To keep the simulation results linked to the physical system, the physical simulator 210 may use a probabilistic estimation technique to approximate the posterior probability of the parameters and initial conditions, given the observed data. This linking technique by the physical simulator 210 may incorporate information from the one or more sensors 206 or any sample point on the system 200A and from any number of measurement devices or sources of data, such as testing and experimental results. Additionally, the linking technique may allow the physical simulator to estimate a minimum number of samples and their locations to bound a possible deviation of the model from the observed properties of the system 200A. The linking technique by the physical simulator 210 may also allow for the estimation of the state of other physical components of the system 200A (e.g., the piping and valve system 204) that maximize the posterior probability of the physical components given the observed properties of the system 200A. Specifically, estimating the posterior probability of the state of physical components of the system 200A may allow the physical simulator 210 to probabilistically rank possible causes of a process upset, such as due to physical defects or misbehavior. As previously described, the physical simulator 210 may then pass the data from the one or more sensors 206 to the reinforcement learning module 208.

The physical simulator 210 may be used to generate data to pre-train a reinforcement learning policy so that it may be close to optimal before deployment. Because reinforcement learning may be considered to be sample inefficient, pretraining allows the system 200C to minimize the number of samples that may be needed to be collected after deployment. The physical simulator 210 may also generate features that encode the state and actions of the reinforcement learning algorithm and may take in a form that is amenable to reinforcement learning, such as a vector of real numbers. The physical simulator 210 may minimize reliance on coarse-grained features such as flow rate or composition of a particular inlet or outlet stream, which may use extensive physical sampling of the system and may not provide real-time visibility into the internal state of the sorbent or how much lithium may currently be adsorbed by the sorbent. After deployment of the reinforcement learning model, the physical simulator 210 may be used as a world model to assist with rolling out particular action sequences and to help identify a sequence of actions that may lead to an optimal reward.

The reinforcement learning module 208 may evaluate the current state of the system 200A based on the output of the physical simulator 210 and may select an action to adjust the controls. Specifically, the reinforcement learning module 208 may use an RL control algorithm to learn the optimal actions to take in response to real-time data from the sensors 206 compared against the physical simulator 210 in order to maximize lithium recovery while minimizing the co-extraction of unwanted elements and operational costs. This learning process occurs through a feedback loop, where the reinforcement learning module 208 continuously updates its control policies based on the observed impacts of previous actions. For example, as fluid exits each extraction column 202 in each stage, the sensors 206 may record measurements, and the physical simulator 210 may use this measurement data from the exit locations as feedback for linking the physical simulator 210 to the physical behavior of the system 200A. The output from the linked physical simulator 210 and the observed data feed from the one or more sensors 206 may be fed into the RL control algorithm of the reinforcement learning module 208. Further adjustments may be made to the controls to optimize the process.

The control polices may correspond to operation parameters of the extraction columns 202 that may be grouped by stages of the direct lithium extract process that may include, among other things, the loading stage, the brine displacement stage, the stripping stage, and the column regeneration stage. The loading stage parameters may include a loading stage column configuration (e.g., a number of columns in parallel, a number of groups of parallel columns in series), a brine flow rate, a brine temperature, and a loading stage residence time. The brine displacement stage parameters may include a displacement stage column configuration, a brine displacement solution flow rate, a temperature, a composition, and a displacement stage residence time. The stripping stage parameters may include a stripping stage column configuration, stripping process parameters, and a stripping stage residence time. The column regeneration stage parameters may include a regeneration stage column configuration and regeneration process parameters. Other miscellaneous parameters may also be included, such as a machine maintenance interval or frequency to, for example, replace or replenish sorbent in the extraction columns 202.

In each stage of the DLE process, the reinforcement learning module 208 may make real-time adjustments to the operational parameters, ensuring that the process is optimized based on the data from the sensors 206, while obeying the physical constraints of the system 200A and other operator-imposed economic constraints. In one or more embodiments, the reinforcement learning module 208 may control flow rates and temperature to optimize the concentration of lithium extracted. In one or more embodiments, the reinforcement learning module 208 may use less regenerating agents (water, acid, or other stripping agents) to minimize operational costs or may optimize the objectives subject to constraints (e.g., a max amount of reagent used or opex). In one or more embodiments, the reinforcement learning module 208 may modify the configuration of the columns in the loading stage to maximize lithium extraction.

It may be appreciated that the choice of features and data preprocessing steps are specifically tuned to this application. Additionally, certain algorithmic choices may be made to facilitate pre-training the control algorithm at pilot-scale to minimize the amount of time the algorithm may need to spend exploring the space of possible control inputs once running in the production scale facility. Finally, the algorithm may be designed to take into account the physical constraints of the various components in the system as well as economic constraints when choosing actions.

Thus, the system 200A may continue to optimize itself over time, learning to maximize lithium extraction efficiency while minimizing operations costs. Through the use of reinforcement learning, the system 200A may allow for continuous adaptation to changing brine compositions, leading to real-time optimization of lithium extraction processes. It may be appreciated that the system 200A may be independent of any specific DLE technology, allowing for broad applicability across different lithium extraction platforms. Moreover, the system 200A may maximize lithium extraction and impurity rejection while minimizing cost, residence time, and reagent/water consumption.

Referring now to FIG. 2B, a block diagram 200B of an example lithium extraction system is depicted according to one or more embodiments. The block diagram 200B depicts a detailed view of the one or more extraction columns 202 and the piping and valve system 204 depicted in FIG. 2A. The lithium extraction system may include one or more tanks, pumps, shared headers, columns, flow routers, and loops. Flow paths between the shared headers, loops, flow routers, and columns may be bidirectional, while flow paths between the tanks, pumps, and shared headers may be unidirectional. The shared headers may be configured to pump process materials and intermediates to and from the tanks. The loops may connect to all of the columns. For ease of depiction, only two columns are shown in FIG. 2B. However, it may be appreciated that substantially any number of columns may be included in the lithium extraction system. The flow routers may be configured to allow either one flow path or no flow paths to be open at a given time. It may be appreciated that all flow orifices may be configured to take a flow as an input or output depending on the direction of incoming or outgoing fluid flow. It may also be appreciated that different instantiations of the flow routers may have different numbers of orifices and may allow different numbers of flow paths.

FIG. 2C is a block diagrams 200C of the reinforcement learning module 208 and the physical simulator 210 depicted in FIG. 2A, according to one or more embodiments. The reinforcement learning module and the physical simulator may communicate bidirectionally with one another through the environment wrapper. The reinforcement learning module may be contained within a reinforcement learning training loop, may transmit an action vector, and may receive a reward, a state indication, and a rollout end signal. The physical simulator may output simulator dynamics and receive a trigger step and an operation list. The physical simulator may also receive kinetics parameters from a kinetic parameter fitting module configured to fit bench-scale experimental data to kinetic parameters for the physical simulator. The physical simulator may also communicate with a pilot direct lithium extraction circuit (PLC).

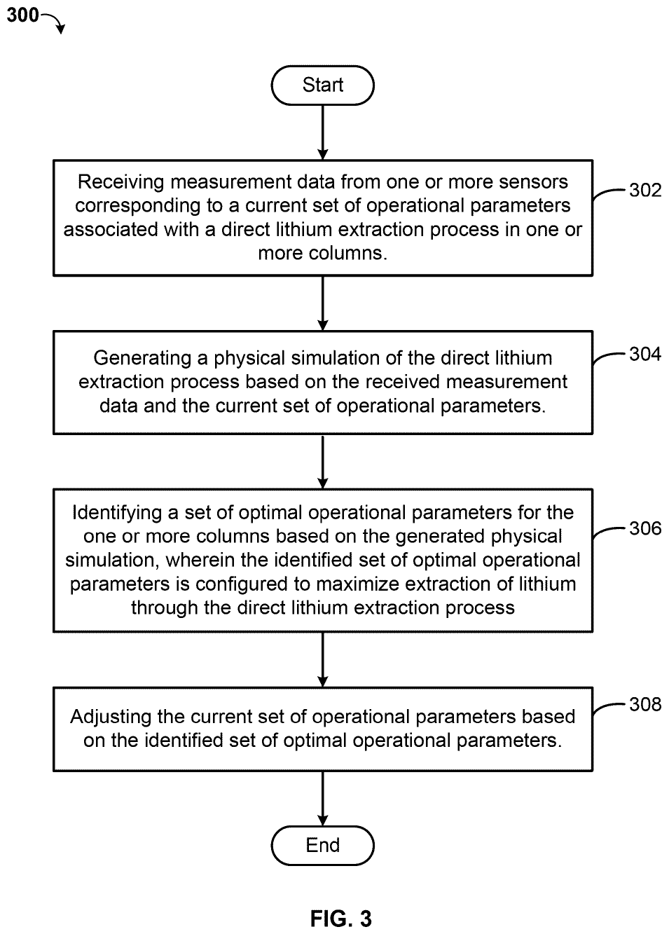

Referring now to FIG. 3, an operational flowchart illustrating the steps of a method 300 carried out by a program that optimizes extraction of lithium through reinforcement learning is depicted.

At 302, the method 300 may include receiving measurement data from one or more sensors corresponding to a current set of operational parameters associated with a direct lithium extraction process in one or more columns. The one or more sensors are inline sensors installed at an inlet or an outlet of each of the one or more columns and include one or more of: a concentration sensor configured to measure a concentration of lithium or impurities in the direct lithium extraction process, a flow meter, a temperature sensor, a pH sensor, or an oxidation-reduction potential (ORP) sensor. In operation, one or more sensors 206 (FIG. 2A) may measure operational parameters of one or more extraction columns 202 (FIG. 2A) and a piping and valve system 204 (FIG. 2A).

At 304, the method 300 may include, generating a physical simulation of the direct lithium extraction process based on the received measurement data and the current set of operational parameters. The physical simulation is linked to physical behavior of the direct lithium extraction process based on approximating a posterior probability associated with parameters of the physical simulation and initial conditions given the received measurement data. The physical simulation also allows for detecting, based on data from the physical simulation and the measurement data received from the one or more sensors, a process upset of the direct lithium extraction process. In response, a posterior probability of states of physical components associated with the direct lithium extraction process is estimate based on based on the data from the physical simulation, and possible causes of the process upset are probabilistically ranking based on the posterior probability. In operation, the physical simulator 210 (FIG. 2A) may generate a physical simulation of the lithium extraction process based on the data collected by the one or more sensors 206 (FIG. 2A) and kinetic parameters determined by a kinetic parameter fitting module 216 (FIG. 2B) based on lab-scale experimental data 220 (FIG. 2B).

At 306, the method 300 may include identifying a set of optimal operational parameters for the one or more columns based on the generated physical simulation. The identified set of optimal operational parameters is configured to maximize extraction of lithium through the direct lithium extraction process. The current and optimal operational parameters include one or more loading stage parameters (e.g., a loading stage column configuration, a brine flow rate, a brine temperature, or a loading stage residence time), brine displacement stage parameters (e.g., a displacement stage column configuration, a brine displacement solution flow rate, a temperature, a composition, or a displacement stage residence time), stripping stage parameters (e.g., a stripping stage column configuration, stripping process parameters, or a stripping stage residence time), column regeneration stage parameters (e.g., a regeneration stage column configuration and regeneration process parameters), or miscellaneous parameters such as a machine maintenance interval or frequency for replacing or replenishing a sorbent in the one or more columns. The loading stage column configuration, the displacement stage column configuration, the stripping stage column configuration, and the regeneration stage column configuration each include a number of columns in parallel and a number of groups of parallel columns in series used for each respective stage. In operation, the reinforcement learning module 208 (FIG. 2A) may determine optimal conditions for the extraction of lithium by the one or more extraction columns 202 (FIG. 2A) based on the data collected by the one or more sensors 206 (FIG. 2A) and the output of the physical simulator 210 (FIG. 2A).

At 308, the method 300 may include adjusting the current set of operational parameters based on the identified set of optimal operational parameters. Adjusting the current set of operational parameters includes one or more of: controlling a flow rate or a temperature of the direct lithium extraction process, adjusting a concentration of one or more regenerating agents associated with the direct lithium extraction process, or modifying a configuration of a loading stage of the one or more columns. In operation, the reinforcement learning module 208 (FIG. 2A) may adjust the parameters of the one or more extraction columns 202 (FIG. 2A) based on the determined optimal parameters. The reinforcement learning module 208 may use feedback learning based on analyzing the updated operational parameters to determine whether such parameters are, in fact, optimal.

It may be appreciated that FIG. 3 provides only an illustration of one implementation and does not imply any limitations with regard to how different embodiments may be implemented. Many modifications to the depicted environments may be made based on design and implementation requirements.

FIG. 4 is a block diagram 400 of internal and external components of computers depicted in FIG. 1 in accordance with an illustrative embodiment. It should be appreciated that FIG. 4 provides only an illustration of one implementation and does not imply any limitations with regard to the environments in which different embodiments may be implemented. Many modifications to the depicted environments may be made based on design and implementation requirements.

Computer 102 (FIG. 1) and server computer 114 (FIG. 1) may include respective sets of internal components 800A,B and external components 900A,B illustrated in FIG. 4. Each of the sets of internal components 800 include one or more processors 820, one or more computer-readable RAMs 822 and one or more computer-readable ROMs 824 on one or more buses 826, one or more operating systems 828, and one or more computer-readable tangible storage devices 830.

Processor 820 is implemented in hardware, firmware, or a combination of hardware and software. Processor 820 is a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, processor 820 includes one or more processors capable of being programmed to perform a function. Bus 826 includes a component that permits communication among the internal components 800A,B.

The one or more operating systems 828, the software program 108 (FIG. 1) and the Reinforcement Learning Program 116 (FIG. 1) on server computer 114 (FIG. 1) are stored on one or more of the respective computer-readable tangible storage devices 830 for execution by one or more of the respective processors 820 via one or more of the respective RAMs 822 (which typically include cache memory). In the embodiment illustrated in FIG. 4, each of the computer-readable tangible storage devices 830 is a magnetic disk storage device of an internal hard drive. Alternatively, each of the computer-readable tangible storage devices 830 is a semiconductor storage device such as ROM 824, EPROM, flash memory, an optical disk, a magneto-optic disk, a solid state disk, a compact disc (CD), a digital versatile disc (DVD), a floppy disk, a cartridge, a magnetic tape, and/or another type of non-transitory computer-readable tangible storage device that can store a computer program and digital information.

Each set of internal components 800A,B also includes a R/W drive or interface 832 to read from and write to one or more portable computer-readable tangible storage devices 936 such as a CD-ROM, DVD, memory stick, magnetic tape, magnetic disk, optical disk or semiconductor storage device. A software program, such as the software program 108 (FIG. 1) and the Reinforcement Learning Program 116 (FIG. 1) can be stored on one or more of the respective portable computer-readable tangible storage devices 936, read via the respective R/W drive or interface 832 and loaded into the respective hard drive 830.

Each set of internal components 800A, B also includes network adapters or interfaces 836 such as a TCP/IP adapter cards; wireless Wi-Fi interface cards; or 3G, 4G, or 5G wireless interface cards or other wired or wireless communication links. The software program 108 (FIG. 1) and the Reinforcement Learning Program 116 (FIG. 1) on the server computer 114 (FIG. 1) can be downloaded to the computer 102 (FIG. 1) and server computer 114 from an external computer via a network (for example, the Internet, a local area network or other, wide area network) and respective network adapters or interfaces 836. From the network adapters or interfaces 836, the software program 108 and the Reinforcement Learning Program 116 on the server computer 114 are loaded into the respective hard drive 830. The network may comprise copper wires, optical fibers, wireless transmission, routers, firewalls, switches, gateway computers and/or edge servers.

Each of the sets of external components 900A,B can include a computer display monitor 920, a keyboard 930, and a computer mouse 934. External components 900A,B can also include touch screens, virtual keyboards, touch pads, pointing devices, and other human interface devices. Each of the sets of internal components 800A,B also includes device drivers 840 to interface to computer display monitor 920, keyboard 930 and computer mouse 934. The device drivers 840, R/W drive or interface 832 and network adapter or interface 836 comprise hardware and software (stored in storage device 830 and/or ROM 824).

Some embodiments may relate to a system, a method, and/or a computer program product at any possible technical detail level of integration. The computer program product may include a computer-readable non-transitory storage medium (or media) having computer readable program instructions thereon for causing a processor to carry out operations.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer readable media according to various embodiments. In this regard, cache block in the flowchart or block diagrams may represent a module, segment, or portion of instructions, which comprises one or more executable instructions for implementing the specified logical function(s). The method, computer system, and computer program product may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The above principles underlying the extraction of lithium apply to other material extraction plants and facilities, as well as other like industrial and manufacturing settings.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware may be designed to implement the systems and/or methods based on the description herein.

No element, act, or instruction used herein should be construed as critical or essential unless explicitly described as such. Also, as used herein, the articles “a” and “an” are intended to include one or more items and may be used interchangeably with “one or more. ” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

The descriptions of the various aspects and embodiments have been presented for purposes of illustration but are not intended to be exhaustive or limited to the embodiments disclosed. Even though combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of optimizing extraction of lithium through reinforcement learning, executable by a processor, comprising:
receiving measurement data from one or more sensors corresponding to a current set of operational parameters associated with a direct lithium extraction process in one or more columns;
generating a physical simulation of the direct lithium extraction process based on the received measurement data and the current set of operational parameters;
identifying a set of optimal operational parameters for the one or more columns based on the generated physical simulation, wherein the identified set of optimal operational parameters is configured to maximize extraction of lithium through the direct lithium extraction process; and
adjusting the current set of operational parameters based on the identified set of optimal operational parameters.

2. The method of claim 1, wherein the one or more sensors are inline sensors installed at an inlet or an outlet of each of the one or more columns and comprise one or more of: a concentration sensor configured to measure a concentration of lithium or impurities in the direct lithium extraction process, a flow meter, a temperature sensor, a pH sensor, or an oxidation-reduction potential (ORP) sensor.

3. The method of claim 1, wherein the one or more operational parameters comprises one or more of:
loading stage parameters comprising one or more of: a loading stage column configuration, a brine flow rate, a brine temperature, or a loading stage residence time;
brine displacement stage parameters comprising one or more of: a displacement stage column configuration, a brine displacement solution flow rate, a temperature, a composition, or a displacement stage residence time;
stripping stage parameters comprising one or more of: a stripping stage column configuration, stripping process parameters, or a stripping stage residence time;
column regeneration stage parameters comprising one or more of: a regeneration stage column configuration and regeneration process parameters; or
a machine maintenance interval or frequency for replacing or replenishing a sorbent in the one or more columns,
wherein the loading stage column configuration, the displacement stage column configuration, the stripping stage column configuration, and the regeneration stage column configuration each comprise a number of columns in parallel and a number of groups of parallel columns in series used for each respective stage.

4. The method of claim 1, wherein adjusting the current set of operational parameters comprises one or more of:
controlling a flow rate or a temperature of the direct lithium extraction process;
adjusting a concentration of one or more regenerating agents associated with the direct lithium extraction process; or
modifying a configuration of a loading stage of the one or more columns.

5. The method of claim 1, further comprising detecting, based on data from the physical simulation and the measurement data received from the one or more sensors, a process upset of the direct lithium extraction process.

6. The method of claim 5, further comprising, in response to detecting the process upset:
estimating, based on the data from the physical simulation, a posterior probability of states of physical components associated with the direct lithium extraction process; and
probabilistically ranking possible causes of the process upset based on the posterior probability.

7. The method of claim 1, wherein the physical simulation is linked to physical behavior of the direct lithium extraction process based on approximating a posterior probability associated with parameters of the physical simulation and initial conditions, given the received measurement data.

8. A computer system for optimizing extraction of lithium through reinforcement learning, the computer system comprising:
one or more non-transitory computer-readable storage media configured to store computer program code; and
one or more computer processors configured to access said computer program code and operate as instructed by said computer program code, said computer program code including:
receiving code configured to cause the one or more computer processors to receive measurement data from one or more sensors corresponding to a current set of operational parameters associated with a direct lithium extraction process in one or more columns;
generating code configured to cause the one or more computer processors to generate a physical simulation of the direct lithium extraction process based on the received measurement data and the current set of operational parameters;
identifying code configured to cause the one or more computer processors to identify a set of optimal operational parameters corresponding to the one or more columns based on the generated physical simulation, wherein the identified set of optimal operational parameters is configured to maximize extraction of lithium through the lithium extraction process; and
adjusting code configured to cause the one or more computer processors to adjust the current set of operational parameters based on the identified set of optimal operational parameters.

9. The computer system of claim 8, wherein the one or more sensors are inline sensors installed at an inlet or an outlet of each of the one or more columns and comprise one or more of:
a concentration sensor configured to measure a concentration of lithium or impurities in the direct lithium extraction process, a flow meter, a temperature sensor, a pH sensor, or an oxidation-reduction potential (ORP) sensor.

10. The computer system of claim 8, wherein the one or more operational parameters comprises one or more of:
loading stage parameters comprising one or more of: a loading stage column configuration, a brine flow rate, a brine temperature, or a loading stage residence time;
brine displacement stage parameters comprising one or more of: a displacement stage column configuration, a brine displacement solution flow rate, a temperature, a composition, or a displacement stage residence time;
stripping stage parameters comprising one or more of: a stripping stage column configuration, stripping process parameters, or a stripping stage residence time;
column regeneration stage parameters comprising one or more of: a regeneration stage column configuration and regeneration process parameters; or
a machine maintenance interval or frequency for replacing or replenishing a sorbent in the one or more columns,
wherein the loading stage column configuration, the displacement stage column configuration, the stripping stage column configuration, and the regeneration stage column configuration each comprise a number of columns in parallel and a number of groups of parallel columns in series used for each respective stage.

11. The computer system of claim 8, wherein the adjusting code is configured to cause the one or more computer processors to:
control a flow rate or a temperature of the direct lithium extraction process;
adjust a concentration of one or more regenerating agents associated with the direct lithium extraction process; or
modify a configuration of a loading stage of the one or more columns.

12. The computer system of claim 8, further comprising detecting code stored on the one or more non-transitory computer-readable storage media that is configured to cause the one or more computer processors to detect, based on data from the physical simulation and the measurement data received from the one or more sensors, a process upset of the direct lithium extraction process.

13. The computer system of claim 12, further comprising, in response to detecting the process upset:
estimating code stored on the one or more non-transitory computer-readable storage media that is configured to cause the one or more computer processors to estimate, based on the data from the physical simulation, a posterior probability of states of physical components associated with the direct lithium extraction process; and
ranking code stored on the one or more non-transitory computer-readable storage media that is configured to cause the one or more computer processors to probabilistically rank possible causes of the process upset based on the posterior probability.

14. The computer system of claim 8, wherein the physical simulation is linked to physical behavior of the direct lithium extraction process based on approximating a posterior probability associated with parameters of the physical simulation and initial conditions, given the received measurement data.

15. A computer program product for optimizing extraction of lithium through reinforcement learning, comprising:
one or more non-transitory computer-readable storage devices; and
program instructions stored on at least one of the one or more computer-readable storage devices, the program instructions being executable by one or more processors and configured to cause the one or more processors to:
receive measurement data from one or more sensors corresponding to a current set of operational parameters associated with a direct lithium extraction process in one or more columns;
generate a physical simulation of the direct lithium extraction process based on the received measurement data and the current set of operational parameters
identify a set of optimal operational parameters corresponding to the one or more columns based on the generated physical simulation, wherein the identified set of optimal operational parameters is configured to maximize extraction of lithium through the lithium extraction process; and
adjust the current set of operational parameters based on the identified set of optimal operational parameters.

16. The computer program product of claim 15, wherein the one or more sensors are inline sensors installed at an inlet or an outlet of each of the one or more columns and comprise one or more of: a concentration sensor configured to measure a concentration of lithium or impurities in the direct lithium extraction process, a flow meter, a temperature sensor, a pH sensor, or an oxidation-reduction potential (ORP) sensor.

17. The computer program product of claim 15, wherein the one or more operational parameters comprises one or more of:
loading stage parameters comprising one or more of: a loading stage column configuration, a brine flow rate, a brine temperature, or a loading stage residence time;
brine displacement stage parameters comprising one or more of: a displacement stage column configuration, a brine displacement solution flow rate, a temperature, a composition, or a displacement stage residence time;
stripping stage parameters comprising one or more of: a stripping stage column configuration, stripping process parameters, or a stripping stage residence time;
column regeneration stage parameters comprising one or more of: a regeneration stage column configuration and regeneration process parameters; or
a machine maintenance interval or frequency for replacing or replenishing a sorbent in the one or more columns,
wherein the loading stage column configuration, the displacement stage column configuration, the stripping stage column configuration, and the regeneration stage column configuration each comprise a number of columns in parallel and a number of groups of parallel columns in series used for each respective stage.

18. The computer program product of claim 15, wherein the program instructions configured to cause the one or more processors to adjust the current set of operational parameters comprises program instructions configured to perform one or more of:
controlling a flow rate or a temperature of the direct lithium extraction process;
adjusting a concentration of one or more regenerating agents associated with the direct lithium extraction process; or
modifying a configuration of a loading stage of the one or more columns.

19. The computer program product of claim 15, wherein the program instructions are further configured to cause the one or more processors to:
detect, based on data from the physical simulation and the measurement data received from the one or more sensors, a process upset of the direct lithium extraction process;
in response to detecting the process upset, estimate, based on the data from the physical simulation, a posterior probability of states of physical components associated with the direct lithium extraction process; and
probabilistically rank possible causes of the process upset based on the posterior probability.

20. The computer program product of claim 15, wherein the physical simulation is linked to physical behavior of the direct lithium extraction process based on approximating a posterior probability associated with parameters of the physical simulation and initial conditions, given the received measurement data.
